(19) United States
(12) Patent Application Publication
(10) Pub. No.: US 2025/0044663 A1
(43) Pub. Date: Feb. 6, 2025

(54) Optical Device

(71) Applicant: Nippon Telegraph and Telephone Corporation, Tokyo (JP)

(72) Inventors: Hidetaka Nishi, Musashino-shi, Tokyo (JP); Shinji Matsuo, Musashino-shi, Tokyo (JP); Toru Segawa, Musashino-shi, Tokyo (JP)

(21) Appl. No.: 18/716,487

(22) PCT Filed: Dec. 8, 2021
(86) PCT No.: PCT/JP2021/045058

§ 371 Date: Jun. 4, 2024

(51) Int. Cl. G02F 1/377; G02F 1/355; H01S 5/042; H01S 5/30

(52) U.S. Cl. CPC G02F 1/377; G02F 1/3556; H01S 5/0421; H01S 5/3013

(57) ABSTRACT

An optical device includes a cladding layer and a core formed on the cladding layer and including a crystal of a III-V compound semiconductor crystal. The core has a plurality of first regions and second regions periodically connected in series. In addition, adjacent first regions and second regions have reversals of polarization. In the plurality of first regions and second regions included in the core, the adjacent first region and second region have reversals of polarization in a direction perpendicular to a waveguide direction.

### TECHNICAL FIELD

The present invention relates to an optical device.

### BACKGROUND ART

A short pulsed laser achieved by development and substantiation of Kerr-lens mode-locking has made a major breakthrough in generation of ultrashort pulsed light on the order of femtoseconds, which has significantly advanced industrial and medical applications in addition to academic researches in the field of physical chemistry. Kerr-lens mode-locking is a technique in which pulsed light is made incident upon an optical resonator including a χ⁽³⁾ medium to obtain a light pulse that is temporally and spatially compressed in a self-convergent manner by a third-order nonlinear optical effect (Kerr effect). As described above, the nonlinear permittivity χ⁽³⁾ greatly affects the performance of the light pulse.

The Kerr effect induces a change in refractive index according to an optical intensity and is expressed as n(ω, I)=n(ω)+n₂I where n(ω, I) is a refractive index dependent on an optical intensity, ω is a frequency of incident light, and I is an optical intensity. Herein, n₂ is a nonlinear refractive index which corresponds to χ⁽³⁾ and depends greatly on materials. A larger value of n₂ enables a larger change in refractive index with a lower optical intensity of incident light, thereby enabling efficient pulse compression.

Today, great progress has been achieved in pulse compression utilizing the Kerr effect in an optical fiber and using a combination of an optical fiber resonator and a dispersion control device, and generation of broadband light (super continuum light) using ultrashort pulsed light obtained by a mode-locked fiber laser has also been proposed and substantiated, leading to development of new light source technology using a short pulsed laser. However, n₂ of glass constituting an optical fiber is small and not efficient at all, and there is demand for further reductions of energy consumption and higher efficiency. In addition, in order to broaden the field of application, it is highly significant to downsize an ultrashort pulsed light source by integrating an input pulsed light source and a pulse compressor.

As a method for effectively increasing n₂, there is proposed a cascaded second-order nonlinear optical effect in which a third-order nonlinear optical effect is effectively obtained by a multistage process of a second-order nonlinear optical effect (Non Patent Literature 1). The principle of a cascaded second-order nonlinear optical effect will be outlined below. While light, or a fundamental wave, propagates through a material having a χ⁽²⁾ nonlinear optical effect, a second harmonic wave is sequentially generated in a propagation direction by the χ⁽²⁾ nonlinear optical effect.

Similarly, a second harmonic wave generated by wavelength conversion sequentially generates a fundamental wave by down-conversion during the propagation. The fundamental wave regenerated in this manner is subjected to a large phase shift after going through wavelength conversion (up-conversion), propagation as a second harmonic wave, and another wavelength conversion (down-conversion). For this reason, this fundamental wave undergoes a larger phase shift than a phase shift that a fundamental wave undergoes based on a third-order nonlinear optical effect (Kerr effect) which a material inherently has, and then, interferes with an incident fundamental wave. In addition, since a phase shift depends on a wavelength conversion efficiency due to a second-order nonlinear optical effect, a phase shift amount depends on an optical intensity of incident light.

In the aforementioned cascaded second-order nonlinear optical effect, an effective nonlinear refractive index n_{2_CSNLE} is expressed by the following Formula (1).

$$\begin{matrix}[ Math . 1 ] & \\ {n}_{2 \_CSNLE} = - \frac{4 π}{c {ε}_{0}} \frac{L}{λ} \frac{{d}_{eff}^{2}}{{n}_{Fund}^{2} {n}_{SHG}} \frac{1}{Δ kL} & ( 1 )\end{matrix}$$

In the above Formula, c is the speed of sound, ε₀ is the vacuum permittivity, L is a propagation length, λ is a wavelength of a fundamental wave, d_{eff} is an effective second-order nonlinear optical constant, n_{Fund} is a refractive index of the fundamental wave, n_{SHG} is a refractive index of a second harmonic wave, and ΔkL is a phase difference between the fundamental wave and the second harmonic wave.

Hereinafter, the third term on the right-hand side of the above Formula is replaced with a as shown in the following Formula (2).

$$\begin{matrix}[ Math . 2 ] & \\ α = \frac{{d}_{eff}^{2}}{{n}_{F u n d}^{2} {n}_{S H G}} & ( 2 )\end{matrix}$$

For example, in lithium niobate (LN) and lithium tantalate (LT) which are most widely used as second-order nonlinear optical materials, when L=10 mm, n_{Fund}=N_{SHG}=2, λ=1 μm, d_{eff}=10 pm/V, and ΔkL=21, n_{2_CSNLE} is about 1×10⁻¹² cm²/W, an extremely large value as compared with n₂ of an optical fiber (glass), that is, about 2×10⁻¹⁶ cm²/W.

### CITATION LIST

### Non Patent Literature

Non Patent Literature 1: R. DeSalvo, et al., “Self-focusing and self-defocusing by cascaded second-order effects in KTP”, Optics Letters, Vol. 17, pp. 28-30, 1992.

### SUMMARY OF INVENTION

### Technical Problem

A cascaded second-order nonlinear optical effect is typically produced using a ceramic material such as LN, LT, and KTP. These ceramic materials have good nonlinear constants and have been widely used as second-order nonlinear optical materials from a historical perspective but are still required to have higher efficiency.

The present invention has been made to solve the problem, and an object of the present invention is to obtain a cascaded second-order nonlinear optical effect more efficiently.

### Solution to Problem

An optical device according to the present invention includes a cladding layer and a core formed on the cladding layer and including a crystal of a III-V compound semiconductor, in which the core has a plurality of regions periodically connected in series, and adjacent regions have a reversal of polarization.

### Advantageous Effects of Invention

As described above, according to the present invention, it is possible to obtain a cascaded second-order nonlinear optical effect more efficiently.

### BRIEF DESCRIPTION OF DRAWINGS

FIG. 1 is a cross-sectional view illustrating a configuration of an optical device according to an embodiment of the present invention.

FIG. 2 is a characteristic diagram illustrating a calculated result of α dependence of an effective nonlinear refractive index n_{2_CSNLE} in a case where a fundamental wave has a wavelength of 1.55 μm and a core 102 has a propagation length of 1 mm to 10 mm.

FIG. 3A is a cross-sectional view for describing a method for manufacturing the optical device according to the embodiment of the present invention, illustrating the optical device in the process of being manufactured.

FIG. 3B is a cross-sectional view for describing the method for manufacturing the optical device according to the embodiment of the present invention, illustrating the optical device in the process of being manufactured.

FIG. 3C is a cross-sectional view for describing the method for manufacturing the optical device according to the embodiment of the present invention, illustrating the optical device in the process of being manufactured.

FIG. 3D is a cross-sectional view for describing the method for manufacturing the optical device according to the embodiment of the present invention, illustrating the optical device in the process of being manufactured.

FIG. 3E is a cross-sectional view for describing the method for manufacturing the optical device according to the embodiment of the present invention, illustrating the optical device in the process of being manufactured.

FIG. 3F is a cross-sectional view for describing the method for manufacturing the optical device according to the embodiment of the present invention, illustrating the optical device in the process of being manufactured.

FIG. 4A is a plan view illustrating a configuration of another optical device according to the embodiment of the present invention.

FIG. 4B is a cross-sectional view illustrating the configuration of the other optical device according to the embodiment of the present invention.

### DESCRIPTION OF EMBODIMENTS

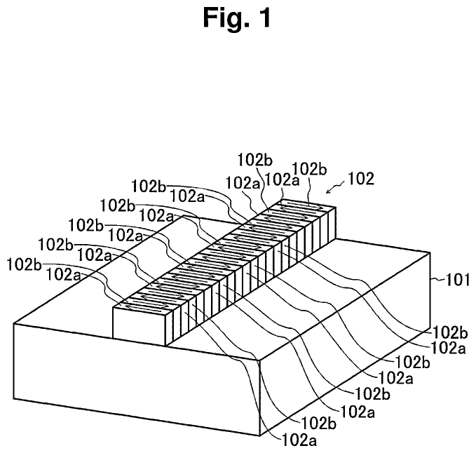

An optical device according to an embodiment of the present invention will hereinafter be described with reference to FIG. 1. The optical device includes a cladding layer 101 and a core 102 formed on the cladding layer 101 and including a crystal of a III-V compound semiconductor.

The core 102 has a plurality of first regions 102a and second regions 102b periodically connected in series. In addition, adjacent first regions 102a and second d regions 102b have reversals of polarization. In the plurality of first regions 102a and second regions 102b included in the core 102, the adjacent first regions 102a and second regions 102b have reversals of polarization in a direction perpendicular to a waveguide direction.

For example, as indicated by an arrow in FIG. 1, the adjacent first regions 102a and second regions 102b are made to have reversals of polarization in a direction perpendicular to the waveguide direction and parallel to the plane of the cladding layer 101. Alternatively, the adjacent first regions 102a and second regions 102b may have a structure with reversals of polarization in a direction perpendicular to the waveguide direction and perpendicular to the plane of the cladding layer 101. These structures are appropriately set according to a polarization direction of light of interest (wavelength converted light).

The cladding layer 101 includes, for example, SiO₂. The core 102 (first regions 102a and second regions 102b) includes, for example, AlGaAs (Al composition: up to 0.2). A band gap of AlGaAs is appropriately designed to allow SHG light to transmit through the core 102. The band gap of AlGaAs is controlled by the Al composition. Designing the band gap to allow passage of SHG light makes it possible to obtain an effect of reducing optical loss attributed to two-photon absorption in a semiconductor.

Although not illustrated in FIG. 1, an upper cladding may be disposed on the cladding layer 101 to cover the core 102. The upper cladding is formed from an insulating material such as SiO₂. The refractive index of AlGaAs at a wavelength of 1.55 μm is 3.28, and the refractive index of SiO₂ at a wavelength of 1.55 μm is 1.44. Accordingly, a large difference in refractive index is obtained between the cladding layer 101 (upper cladding) and the core 102, which enables high optical confinement in the core 102. Furthermore, AlGaAs has a second-order nonlinear optical constant of about 120 pm/V which is extremely larger than values of lithium niobate (LN) and lithium tantalate (LT) (10 to 30 pm/V).

The first regions 102a and second regions 102b have a structure in which domains are periodically inverted (poled) in a propagation direction so as to satisfy a quasi-phase matching (QPM) condition in the core 102 (periodically poled structure). A period in which the polarization is inverted, or a length of the first regions 102a and second regions 102b in the waveguide direction (thicknesses), is set to a value that matches the QPM condition, that is, for example, 10 μm or less. In addition, the dimension of a cross section of the core 102 is appropriately designed to satisfy a desired phase matching condition as well as the QPM period while satisfying a single mode condition.

In a case where propagation light has a wavelength of 1.55 μm and a propagation length is 10 mm, an effective nonlinear refractive index n_{2_CSNLE} is about 3.7 cm²/W, which is about 50 times larger than an effective nonlinear refractive index of LN or LT. In addition, it is possible to obtain a value larger than a third-order nonlinear refractive index n₂ of an AlGaAs optical waveguide. In other words, in the core 102 having the periodically poled structure by the first regions 102a and the second regions 102b, it is possible to obtain an excellent cascaded second-order nonlinear optical effect with high efficiency.

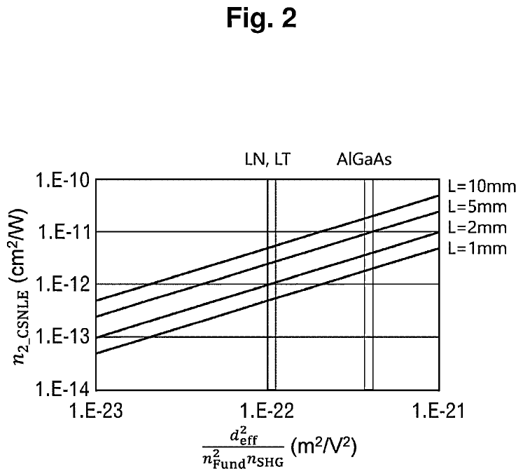

FIG. 2 illustrates a calculated result of α dependence of an effective nonlinear refractive index n_{2_CSNLE} in a case where a fundamental wave has a wavelength of 1.55 μm and the core 102 has a propagation length of 1 mm to 10 mm. Note that a is given as shown in Formula (2). A semiconductor material (AlGaAs) is typically higher in refractive index than a ceramic material such as LN and LT. In other words, since n_{Fund} and n_{SHG} become large, it is important to select a second-order nonlinear optical material system having a sufficiently large d_{eff} in order to increase α.

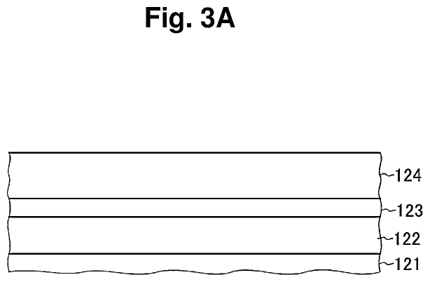

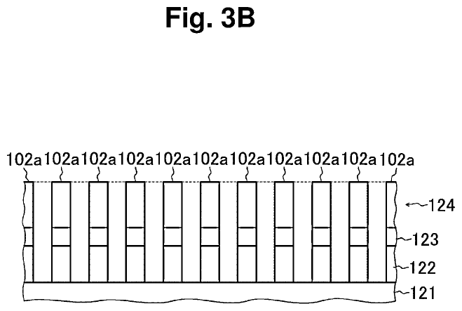

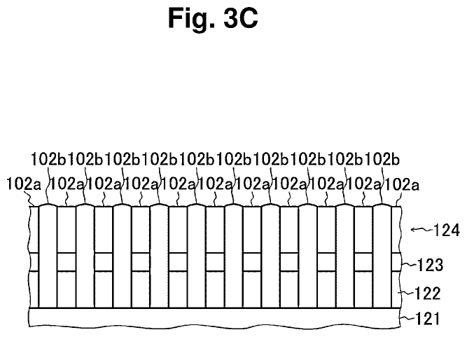

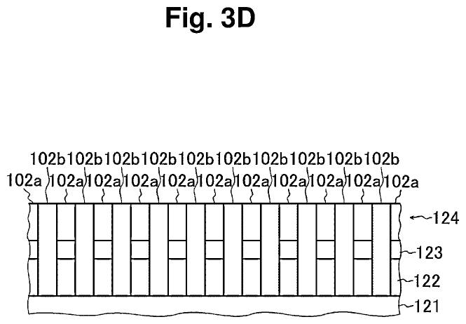

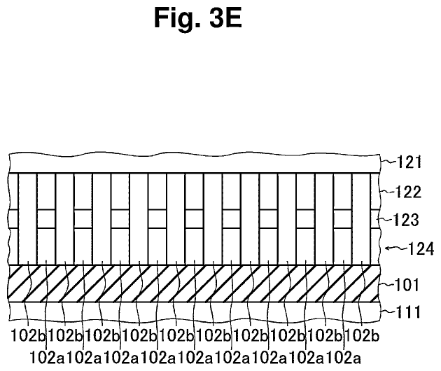

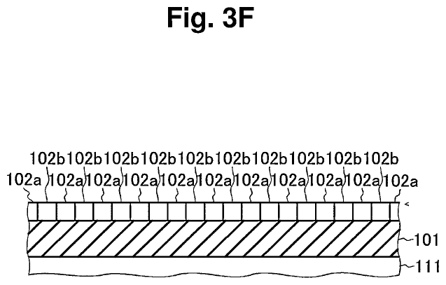

Next, a method for manufacturing the optical device according to an embodiment of the present invention will be described with reference to FIGS. 3A to 3F. First, as illustrated in FIG. 3A, a crystal of a Ge layer 122 including Ge and a crystal of a buffer layer 123 including GaAs are grown on a growth substrate 121 including GaAs. In the GaAs growth substrate 121, the orientation of the principal plane is (100). Alternatively, the principal plane of the GaAs growth substrate 121 may be temporarily deviated from the (100) orientation.

Furthermore, a crystal of a domain-inverted layer 124 including AlGaAs is grown on the buffer layer 123. When the Ge layer 122 is formed on the GaAs growth substrate 121, the domain (polarization direction) of the GaAs crystal to be grown on the Ge layer 122 and that of the growth substrate 121 are inverted. In a case where AlGaAs is directly grown on the Ge layer 122, it is difficult to enhance the quality of a growing crystal due to lattice mismatch. For this reason, after the buffer layer 123 including GaAs is formed, AlGaAs is grown to form the domain-inverted layer 124. Note that the domain of the buffer layer 123 is also inverted.

Next, by known lithography and etching techniques, the Ge layer 122, the buffer layer 123, and the domain-inverted layer 124 are formed into line/space patterns having a period that matches the QPM condition, thereby forming a plurality of first regions 102a in the domain-inverted layer 124 as illustrated in FIG. 3B. In the line/space patterning of the Ge layer 122, the buffer layer 123, and the domain-inverted layer 124, a surface of the growth substrate 121 is exposed at space portions.

Next, a crystal of AlGaAs is grown on the growth substrate 121 exposed at the space portions, and the plurality of second regions 102b is formed as illustrated in FIG. 3C. The second regions 102b grow to fill the space portions. Next, as illustrated in FIG. 3D, chemical mechanical polishing (CMP) is performed to reduce unevenness on a surface of the domain-inverted layer 124, thereby planarizing top surfaces of the plurality of alternately arranged first regions 102a and second regions 102b as viewed from the growth substrate 121. In this case, the first regions 102a and second regions 102b are alternately grown in the orientation and the [01-1] orientation toward the waveguide direction.

Next, as illustrated in FIG. 3E, the planarized surfaces of the plurality of alternately arranged first regions 102a and second regions 102b are attached to the cladding layer 101 previously formed on a Si substrate 111. This bonding is performed, for example, by direct bonding. After the bonding, the growth substrate 121 is removed.

Next, the Ge layer 122, the buffer layer 123, the first regions 102a, and the second regions 102b processed into space patterns are polished by CMP, and the Ge layer 122 and the buffer layer 123 are removed, followed by forming the first regions 102a and second regions 102b to have thicknesses corresponding to predetermined core heights and planarizing the surfaces (FIG. 3F).

After the planarization, the core 102 is patterned by known lithography and etching techniques, thereby obtaining the optical device described with reference to FIG. 1.

The manufacturing of the optical device described with reference to FIGS. 3A to 3C may employ the technique recited in Reference Literature 1. In addition, the planarized surfaces of the plurality of alternately arranged first regions 102a and second regions 102b are bonded to the cladding layer 101 by forming an interface layer including SiO₂, Al₂O₃, or the like on the planarized surfaces of the plurality of first regions 102a and second regions 102b and by directly bonding the interface layer and the cladding layer 101. Such direct bonding may employ typically used hydrophilic bonding or surface activated bonding.

Note that the aforementioned material structure is an example, and any compound semiconductor material system may be used as long as the system similarly exhibits a cascaded second-order nonlinear optical effect with high efficiency and produces a domain-inverted structure. Furthermore, the present technology is also useful for development of recent high-profile light source technology in a mid-infrared region having wavelengths of from 2000 nm to several 10 μm. On the other hand, since SiO₂ exhibits large loss with a wavelength over 4 μm, forming the cladding layer 101 from a material with high transmittance in a desired wavelength band such as SiN, Al₂O₃, or air enables suppression of the loss to a wavelength of about 7 μm.

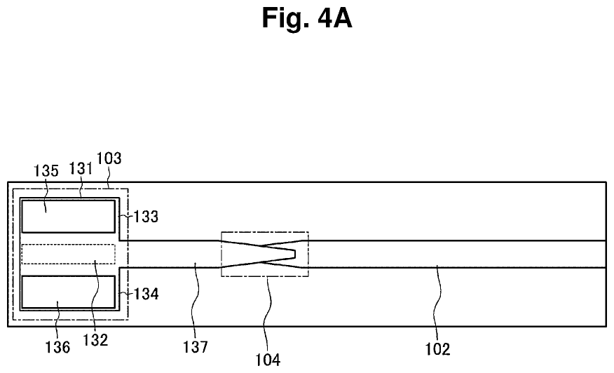

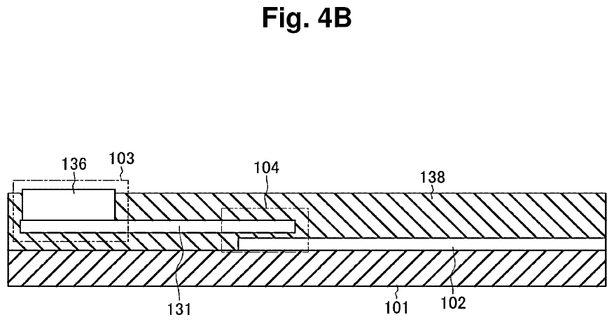

The optical device may include a waveguide-type semiconductor laser 103 formed on the cladding layer 101 and configured to emit pulsed light (FIGS. 4A and 4B). The semiconductor laser 103 includes an active layer 132 formed in a semiconductor layer 131 including a III-V compound semiconductor such as InP and includes a p-type p-semiconductor layer 133 and an n-type n-semiconductor layer 134 which are formed in the semiconductor layer 131 and sandwich the active layer 132. A diffraction grating (not illustrated) is formed on the active layer 132 to constitute a resonator. In addition, the p-semiconductor layer 133 and the n-semiconductor layer 134 form a current injection structure. A p-electrode 135 is formed in the p-semiconductor layer 133, and an n-electrode 136 is formed in the n-semiconductor layer 134. The semiconductor laser 103 may have a typical laser structure as shown in Reference Literature 2. For example, the semiconductor laser 103 emits short-pulsed light by gain switching as described in Reference Literature 3.

The pulsed light oscillated by the semiconductor laser 103 is emitted to an optical waveguide of a laser core 137 including InP. The optical waveguide of the laser core 137 is optically coupled to an optical waveguide of the core 102 at an optical joint 104 having a counter tapered structure. On the cladding layer 101, an upper cladding layer 138 is formed to cover the core 102, the semiconductor laser 103, and the laser core 137. The pulsed light emitted to the optical waveguide of the laser core 137 is made incident by the optical joint 104 upon the optical waveguide of the core 102 with low loss.

As described above, according to the optical device of the embodiment, a nonlinear optical element that enables wavelength conversion by the core 102 having a periodically poled structure and a semiconductor laser serving as a light source are integrated on the cladding layer 101. Ceramic materials such as LN, LT, and KTP employed in the related art enable cascaded second-order nonlinear optical effect processes but require a separate external input pulsed light source, which creates a major challenge of downsizing and high integration of a pulsed light source module. In contrast, the optical device of the embodiment easily enables downsizing and high integration of a pulsed light source module.

As described above, according to the present invention, a core is formed of a crystal of a III-V compound semiconductor and has a plurality of regions periodically connected in series in which adjacent regions have reversals of polarization. Accordingly, a cascaded second-order nonlinear optical effect is obtained with higher efficiency.

Note that the present invention is not limited to the above embodiment, and it is clear that various modifications and combinations can be implemented by those skilled in the art without departing from the technical spirit of the present invention.
[Reference Literature 1] X. Yu et al., “Efficient continuous wave second harmonic generation pumped at 1.55 μm in quasi-phase-matched AlGaAs waveguides”, Optics Express, vol. 13, no. 26, pp. 10742-10748, 2005.
[Reference Literature 2] T. Fujii et al., “Multiwavelength membrane laser array using selective area growth on directly bonded InP on SiO₂/Si”, Optical Society of America, vol. 7, no. 7, pp. 838-846, 2020.
[Reference Literature 3] Z. Liu et al., “50-GHz Repetition Gain Switching Using a Cavity-Enhanced DFB Laser Assisted by Optical Injection Locking”, Journal of Lightwave Technology, vol. 38, no. 7, pp. 1844-1850, 2020.

### REFERENCE SIGNS LIST

101 CLADDING LAYER
102 CORE
102a FIRST REGION
102b SECOND REGION

1. An optical device comprising:
a cladding layer; and
a core formed on the cladding layer and including a crystal of a III-V compound semiconductor,
wherein the core has a plurality of regions periodically connected in series, and adjacent regions have a reversal of polarization.

2. The optical device according to claim 1,
wherein the adjacent regions in the plurality of regions included in the core have a reversal of polarization in a direction perpendicular to a waveguide direction.

3. The optical device according to claim 1 comprising:
a semiconductor laser of a waveguide type formed on the cladding layer and configured to emit pulsed light,
wherein the pulsed light emitted from the semiconductor laser is incident upon an optical waveguide of the core.

4. The optical device according to claim 3,
wherein the semiconductor laser comprises:
an active layer including a III-V compound semiconductor; and
a current injection structure including a p-semiconductor layer including a p-type III-V compound semiconductor and an n-semiconductor layer including an n-type III-V compound semiconductor, the p-semiconductor layer and the n-semiconductor layer sandwiching the active layer.

5. The optical device according to claim 2 comprising:
a semiconductor laser of a waveguide type formed on the cladding layer and configured to emit pulsed light,
wherein the pulsed light emitted from the semiconductor laser is incident upon an optical waveguide of the core.
